(19) United States
(12) Patent Application Publication
(10) Pub. No.: US 2005/0253222 A1
(43) Pub. Date: Nov. 17, 2005

(54) Semiconductor devices on misoriented substrates

(76) Inventors: Catherine G. Caneau, Painted Post, NY (US); Georgiy Guryanov, Horsheads, NY (US); Nobuhiko Nishiyama, Painted Post, NY (US)

Correspondence Address: CORNING INCORPORATED, SP-TI-3-1, CORNING, NY, 14831, US

(21) Appl. No.: 10/996,515

(22) Filed: Nov. 24, 2004

Related U.S. Application Data
(63) Continuation-in-part of application No. 10/944,649, filed on Sep. 16, 2004.
(63) Continuation-in-part of application No. 10/848,456, filed on May 17, 2004, now Pat. No. 6,933,539.

(51) Int. Cl. H01L 29/167

(52) U.S. Cl. 257/607

(57) ABSTRACT

A semiconductor device (100) includes a misoriented substrate (240) having a surface area inclined in a range of about 8 to 40 degrees from the {100} plane. At least one highly doped P-type semiconductor layer (106) of a first semiconductor material doped with Carbon (C) is grown over the surface area. At least one highly doped N-type semiconductor layer (104) of a second semiconductor material is grown over the surface area and near the at least one highly doped P-type semiconductor layer (106). A moderately doped P-type layer (60) is grown over the surface area, wherein the moderately doped P-type layer 60 has a third semiconductor material doped with a dopant selected as a member from the group consisting of Zn, Be, Cd and Mg. The devices 100 include VCSELs having tunnel junctions (110) and semiconductor DBRs (230) composed of AlGaInAs/InP or GaInAs/InP layers (2308/2302) on misoriented substrates 240.

### CROSS-REFERENCE TO RELATED APPLICATIONS

This is a continuation-in-part of U.S. patent application Ser. No. U.S. Parent application Ser. No. 10/944,649 filed on U.S. Parent Application Filing Date Sep. 16, 2004, and U.S. application Ser. No. 10/848,456 filed May 17, 2004 the content of which is relied upon and incorporated herein by reference in its entirety, and the benefit of priority under 35 U.S.C. § 120 is hereby claimed.

### BACKGROUND OF THE INVENTION

### Field of the Invention

The present invention relates generally to semiconductor devices, including surface emitting lasers, and particularly to tunnel junctions for long-wavelength vertical cavity surface emitting lasers (VCSELs) that incorporate layers doped with atoms which will outdiffuse.

2. Technical Background

Some electrical devices built from semiconductor layers, such as tunnel junctions (TJ) or heterojunction bipolar transistors (HBT), require layers with very high carrier concentrations(>10¹⁹cm-3, as high as possible) which result in very heavily doped layers. These very high carrier concentrations are achievable only by doping with selected impurities.

Carrier concentration or effective doping concentration is defined by the relationship where n-type carrier concentration=n-type doping concentration−p-type doping concentration in a particular semiconductor layer. Hence, a high n-type carrier concentration requires either an increase in n-type doping concentration or a reduction in the p-type doping concentration such that the resultant in the out-diffused p-type doping concentration is close to zero. However, the maximum n-type carrier concentration level which can be used in a given device is limited. The limit can be imposed by morphology problems above a certain impurity concentration or by saturation of the dopant activation. P-type doping concentration can be reduced simply by not having any intentional p-type doping introduced to that particular layer. However, outdiffusion of impurities (p-type dopants) from other layers unintentionally increases the p-type doping concentration in the layer, resulting in a reduction of the n-type carrier concentration.

It is known that there are some semiconductor devices that incorporate layers doped with some atoms which will outdiffuse. For example, the p-type dopants zinc(Zn) and beryllium (Be), often used in Ill-V semiconductors, are prone to outdiffusion, and their diffusion coefficients increase with their concentration. Hence, there are various kinds of semiconductor devices which require layers highly doped with atoms but which have a tendency to outdiffuse at high concentration, such as the p-type dopants Zn and Be in III-V semiconductors. Good device performance, such as low internal series resistance, requires that the dopants stay localized inside the layers they were introduced in, and not outdiffuse into other layers.

Especially in devices that require a highly n-type doped layer, the situation becomes even worse. The so called, “kick-out” effect has been reported, which explains why the outdiffusion of the p-type dopant atom is enhanced when highly n-type doped layers are grown.

To solve the outdiffusion problem, whenever possible, a p-type dopant with a low diffusion coefficient, such as Carbon, has been employed instead of Zn or Be on a highly doped P-type semiconductor layer grown over conventional {100} planes. Most semiconductor devices built from III-V compounds are grown on substrates whose surfaces are {100} planes or only a few degrees off from {100}, using techniques such as Molecular Beam Epitaxy (MBE) or OrganoMetallic Vapor Phase Epitaxy (OMVPE), or Chemical Beam Epitaxy (CBE). However, in such materials as InP, GaInAsP, or GaInP, carbon is not an easily incorporated as p-type dopant for these materials in the moderately doped P-type layer because of its lower relative bonding strength. Therefore, if these layers are needed as the moderately doped P-type semiconductor layer, we must use other dopants, such as Zn or Be. These layers are important for some cases, such as used as etching stop layers, for preventing oxidation at the surface and for achieving a better bandgap configuration.

Others have used special complicated schemes, requiring crystal growth optimization, such as annealing or substituting special layers to inhibit the out diffusion of Zn or Be from heavily doped layers grown on (100) substrates in the case of n-p-n HBTs. Thus, these techniques are sensitive to many parameters related to crystal quality and optimization is needed for each growth system, increasing the cost and time to fabricate an economical semiconductor device.

In general, doping efficiency depends on the substrate orientation. It is also known that the outdiffusion of certain dopant atoms from the doped layer into adjacent layers can depend on substrate orientation. Angled facets or grooves, and other angled features patterned on the substrate have been used for controlling doping concentration by utilizing the effects of less outdiffusion or different doping efficiencies. However, these techniques require a new structure design.

In the case of Be in GaAs (grown by MBE), off-oriented substrate planes offer a much higher density of steps than {100} substrates, and some types of atoms preferentially adsorb and bond at steps. Therefore, Be doping efficiency is higher on planes with a high density of steps; in addition, since more of the dopant atoms are able to incorporate at steps, fewer of those atoms are incorporated, or quickly displaced into, interstitial positions. Since interstitials are the easily mobile, diffusing, species, a lower density of atoms in those positions means a lower coefficient of diffusion. Diffusion coefficient studies of Be in GaAs grown by MBE on substrates of different orientations have found that (311) is the surface with the highest density of steps and the lowest amount of outdiffusion was, indeed, observed on those planes. This analysis should be the same for other p-type dopants, such as Zn.

An n++InP/p++GaInAs tunnel junction, in which Zn was the only p-dopant introduced to each of the high and moderate doping layers was realized on a (311)B InP substrate, taking advantage of the higher level of both Si and Zn doping on the (311)B substrate

However, because the p-type dopant Zn is prone to outdiffusion to the high doping n-type layer, and their diffusion coefficients increase with their concentration and the kick-out effect mentioned above, it is expected that the very high Zn concentration necessary for the tunnel junction is likely to result in outdiffusion, even if it is less so on the (311) than on (100) substrates, resulting in a lower n-type carrier concentration. In fact, better electrical characteristic has not been observed for this configuration.

Therefore, no total solution has been proposed, so far, to satisfy both desirable highly n-type and p-type carrier concentration layers in a structure requiring a moderately doped p-type layer doped with a dopant which tended to outdiffuse. A highly doped p-type layer with high p-type type carrier concentration was reported, but lowering of the n-type carrier concentration due to the out-diffusion was not solved. Because the relationship of a high n-type carrier concentration in the n++ layer and the need for less outdiffusion in the moderately doped p-layer was not appreciated, this combination was never demonstrated before. Others in the art had observed less diffusion of the moderately doped p-layer on a misoriented substrate, but never thought they should use this phenomenon for increasing the n++layer carrier concentration. Even though a tunnel junction on (311) with Zn as the dopant, was demonstrated, diffusion was not thought to be a problem, so there was no use of Carbon.

One of the devices which require highly n and p doped layers is a tunnel junction as mentioned above. In general, tunnel junctions can be incorporated as parts of other devices, such as vertical cavity surface emitting lasers (VCSELs). VCSELs have become an important component in data communication systems, even though they present special problems. Currently commercial lasers operate at 850 nm, where the lasers are made using AlAsGaAs/GaAs semiconductor layers on GaAs substrates. In these lasers the mirrors forming the optical cavity are formed using alternating layers of AlAs and GaAs, with the AlAs/AlGaAs mirror on at least one side of the active region. Adjacent to the active region is an n-type spacer layer, on one side, and a p-type spacer layer, on the other, which inject carriers into the active region when a voltage is applied to the laser. One of the approaches to achieving VCSELs lasing at the important telecommunication wavelengths of 1.3 or 1.55 microns is to fabricate the lasers from materials based on InP substrates.

One problem with this approach is the high free carrier absorption in the p-doped layers of the laser. Free-carrier absorption is the phenomenon whereby an electron or hole within a band absorbs radiation by transferring from a low-energy level to an empty high-energy level. This problem becomes worse as the lasing wavelength increases to the longer wavelengths of 1.3 or 1.55 microns. However, free carrier absorption is not as significant a problem for short wavelength VCSELs, such as 850 nm VCSELs.

To make matters worse, the poor mobility of the p-type layers results in a non-uniform current injection. Therefore, thick p-type layers may be needed to make uniform current injection. The increased thickness of the p-type layers increases the total optical absorption by the free carrier absorption.

These long-wavelength VCSEL problems can be addressed by using a tunnel junction to replace most of the p-doped layers with n-doped layers, as has been done recently by several groups. Because n-doped layers have a lower free carrier absorption and a higher mobility of carriers than p-doped layers, total optical absorption can be reduced by the replacement of the p-doped layer with a tunnel junction as well as obtaining a uniform current injection.

In order to make as near ideal a tunnel junction as possible and to minimize the internal series resistance of a VCSEL, it is necessary to obtain very high n- and p-doping in the layers forming the tunnel junction. A high probability of tunneling is required in tunnel junctions. If the tunneling probability increases, the electrical resistance decreases. With the reduction of the electrical resistance, joule heat inside the device decreases. With the reduction of heat, both the maximum output power and temperature performance of the overall device increase.

To increase the tunneling probability, one important way is to ensure that the doping levels of each n-type and p-type layer forming the tunnel junction should be as high as possible. At the same time, a low diffusivity dopant is needed for doping the tunnel junction.

In general, it is already known that tunnel junction characteristics can be improved by increasing the p-type doping level through the use of a highly doped P-type layer doped with carbon. However, further improvement is still desirable.

The detailed nature of how the p-doping and n-doping is used with the particular material systems in the tunnel junction of a long-wavelength VCSEL is a critical issue because the resulting structure must perform multiple functions which include providing a low internal series resistance, funneling of carriers into the active region, and minimizing the effects of free carrier absorption. Hence, a low resistance in the tunnel junction is the key to achieving better performance of VCSELs having tunnel junctions.

Furthermore, another key to improving performance of VCSELs is how to achieve higher reflectivity of distributed Bragg reflectors (DBRs). To achieve high reflectivity, the highest index difference is needed between two materials (having high and low reflective index) consisting of DBR layers. For monolithic semiconductor DBRs grown on the InP substrate, AlGaInAs or GaInAsP as the high index materials and the InP as the low index material are used.

However, it is known that the arsenic (As) (in AlGaInAs and GaInAsP) and the phosphorus (P) elements (in InP and GaInAsP) are intermixed by outdiffusion. Particularly, P can diffuse more than As since the size of the P atom is smaller. This becomes more serious if one grows thicker layers which require a longer growth time. This phenomenon causes the lowering reflectivity of the DBR due to the degradation of interfaces between two materials. However, no solution has yet been found to avoid this problem.

AlGaInAs/InP VCSELs with tunnel junctions have been grown and fabricated successfully on {100} InP substrates. However, VCSELs which can operate injecting currents have not yet been grown and fabricated successfully on misoriented substrates.

Therefore, there is a need for an economical and simple method or device structure to raise maximum carrier concentrations achievable in devices made from flat substrates such as InP, without outdiffusion of p-type dopants such as Zn and Be, for improving device performance such as internal series resistance, and suppressing outdiffusion of P and As in DBRs for improving reflectivity, especially for a VCSEL having tunnel junctions.

### SUMMARY OF THE INVENTION

The present invention teaches a semiconductor device fabricated on a misoriented substrate having a surface area inclined in a range of about 8 to 40 degrees from the {100} plane. At least one highly doped P-type semiconductor layer of a first semiconductor material doped with Carbon (C) is grown over the surface area. At least one highly doped N-type semiconductor layer of a second semiconductor material is grown over the surface area and near the at least one highly doped P-type semiconductor layer. A moderately doped P-type layer is grown over the surface area, wherein the moderately doped P-type layer has a third semiconductor material doped with a dopant selected as a member from the group consisting of Zn, Be, cadmium (Cd) and magnesium (Mg).

One aspect of the invention is that Carbon is introduced in the at least one highly doped P-type semiconductor layer for a high doping concentration greater than about 10¹⁹ cm⁻³.

Additional features and advantages of the invention will be set forth in the detailed description which follows, and in part will be readily apparent to those skilled in the art from that description or recognized by practicing the invention as described herein, including the detailed description which follows, the claims, as well as the appended drawings.

It is to be understood that both the foregoing general description and the following detailed description present embodiments of the invention, and are intended to provide an overview or framework for understanding the nature and character of the invention as it is claimed. The accompanying drawings are included to provide a further understanding of the invention, and are incorporated into and constitute a part of this specification. The drawings illustrate various embodiments of the invention, and together with the description serve to explain the principles and operations of the invention.

### BRIEF DESCRIPTION OF THE DRAWINGS

FIG. 1 is a schematic side view of a tunnel junction structure in a more complex device, such as a vertical cavity surface emitting laser, in one embodiment of the present invention;

FIG. 2 is a schematic side view of an NPN HBT, in a second embodiment of the present invention;

FIG. 3 is a schematic side view of a PNP HBT, in a third embodiment of the present invention;

FIG. 4 is a graph of the current-voltage characteristics of a light emitting diode as the device 100 incorporating the tunnel junction structure 102 of FIG. 1, according to the present invention, compared to the same device structure realized on a conventional (100) substrate;

FIG. 5 is a schematic side view of a vertical cavity surface emitting laser, incorporating the tunnel junction structure of FIG. 1, in a fourth embodiment of the present invention; and

FIG. 6 is a graph of the SIMS data showing the atom profile of aluminum, arsenic and phosphorus for the intensity vs. depth for DBR 230 in the device 100 of FIG. 5, according to the present invention, compared to the same device structure realized on a conventional (100) substrate.

### DETAILED DESCRIPTION OF THE PREFERRED EMBODIMENTS

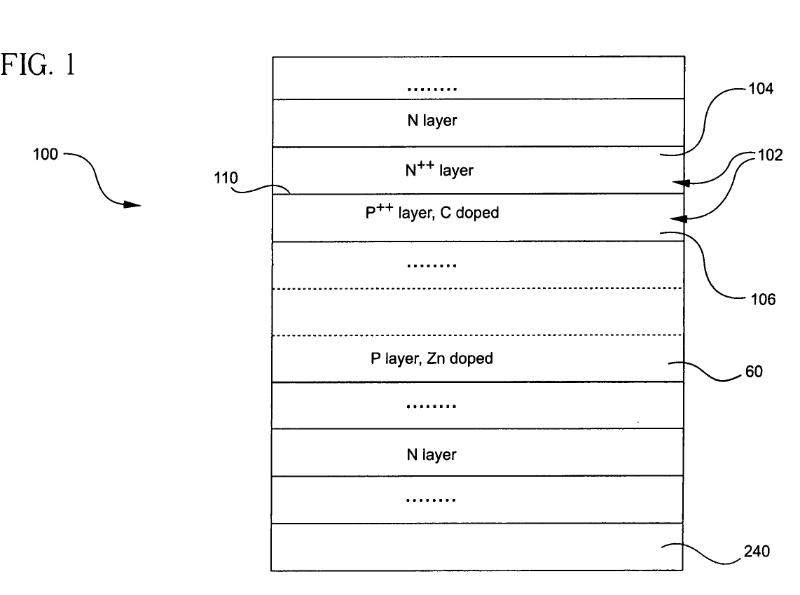

Reference will now be made in detail to the present preferred embodiments of the invention, examples of which are illustrated in the accompanying drawings. Whenever possible, the same reference numerals will be used throughout the drawings to refer to the same or like parts. One embodiment of a semiconductor device of the present invention is shown in FIG. 1, and is designated generally throughout by the reference numeral 100.

Referring to FIG. 1, a semiconductor device 100 includes a misoriented substrate 240 having a surface area inclined in a range of about 8 to 40 degrees from the {100} plane. At least one highly doped P-type semiconductor layer 106 of a first semiconductor material doped with Carbon (C) is grown over the surface area. At least one highly doped N-type semiconductor layer 104 of a second semiconductor material is grown over the surface area and near the at least one highly doped P-type semiconductor layer 106. A moderately doped P-type layer 60 is grown over the surface area, wherein the moderately doped P-type layer 60 has a third semiconductor material doped with a dopant selected as a member from the group consisting of Zn, Be, Cd and Mg. Even though only Zn is shown in the example of FIG. 1, it is to be appreciated that Be, Cd and Mg could be substituted, and the inventive solution would still work.

According to the teachings of the present invention, the structure of an already designed device 100 can simply be grown on a substrate surface of the misoriented substrate 240. The substrate 240 does not require any type of special grooves or other patterning. Preferably, the substrate 240 is flat and its surface is oriented 8-40 degrees away from the (100) orientation. It is to be appreciated that the flat area surface of the misoriented substrate 240 is not flat on the atomic level because one can not cut an atom. However, the substrate 240 is flat in the sense that no special protrusions are needed to make a “facet” or a “groove”. Advantageously, the exactly same layer structure as used in a conventional device on a (100) substrate can be re-used. By simply changing the orientation of the substrate to the slant or tilt of the misoriented substrate 240, device performances, such as internal series resistance improves. However, it is to be appreciated that since properties such as doping efficiency and layer composition depend on the orientation of the surface on which the layers are deposited, calibrations between the structure of an already designed device and the one using the misoriented substrate 240 will need to be performed to achieve the same crystal quality for the layers grown on the misoriented ((n11), where n is 3, for example) substrate 240 as on the previously used type of substrate such as (100). Hence, calibrations need to be performed (doping, . . . ) but the already optimized (by design) layer structure need not be modified with the new misoriented substrate 240.

The misoriented substrate 240, made from InP, GaAs, InAs, GaSb, or GaP, is supplied in such a desired orientation ((n11), where n is 3, for example) by the manufacturer. The substrate orientation is determined by the way the substrate ingot is cut (by the angle between the flat surface of the cut and the axis of the cylindrical ingot).

The misoriented substrate 240 can be A or B type. The B substrate is terminated at the surface by V-group atom (As, P or Sb), while an A substrate is terminated by III-Group (Al, Ga, In). Less out-diffusion is commonly for A than B types. But, the A type substrate can dope higher for a p-type layer and the B substrate can dope higher for an n-type layer.

All of the layers 104, 106, and 60 are grown in succession, in any desired order, on the substrate 240, parallel to the surface of the substrate 240 with III-V materials. The n++ and p++(C doped) layers 104 and 106, respectively, are grown over the same area as the medium doped p layer 60 doped with a dopant which tends to outdiffuse.

The first semiconductor material is a compound of a first member selected from the group consisting of aluminum (Al), gallium (Ga), and indium (In) and a second member selected from the group consisting of arsenic (As), nitrogen (N), and antimony (Sb). Thus, for example, the first semiconductor material of the at least one highly doped P-type semiconductor layer 106 is GaInAs, AlGaInAs, AlInAs, AlAs, GaAs, AlGaAs, GaAsSb, AlAsSb, AlGaAsSb, GaInAsN, InAs, GaSb, or AlGaSb. Similarly, each of the second, and third semiconductor material is a compound of a first member selected from the group consisting of aluminum (Al), gallium (Ga), and indium (In) and a second member selected from the group consisting of arsenic (As), nitrogen (N), phosphorus (P) and antimony (Sb). For, example the second semiconductor material of the at least one highly doped N-type semiconductor layer 104 is GaInAs, AlGaInAs, AlInAs, AlAs, GaAs, AlGaAs, GaAsSb, AlAsSb, AlGaAsSb, InP, GaInAsP, AlGaInP, GaInP, AlInP, GaInAsN, InAs, GaSb, AlGaSb, GaP, AlP, or AlGaP. Finally, the third semiconductor material of the moderately doped P-type layer 60 is also GaInAs, AlGaInAs, AlInAs, AlAs, GaAs, AlGaAs, GaAsSb, AlAsSb, AlGaAsSb, InP, GaInAsP, AlGaInP, GaInP, AlInP, GaInAsN, InAs, GaSb, AlGaSb, GaP, AlP, or AlGaP. Preferably, at least one of the highly doped layers 104 or 106 has a thickness ≦30 nm.

As is known, the terms “below”, “above”, and any other words implying a certain sequence could be inverted in any device 100. For example, it is not necessary for the layers to form a pn junction by p++ and n++. A layer structure, such as n++/p moderately doped/p++ can also benefit from the teachings of the present invention. Only a tunnel junction structure 102 requires certain adjacent layers where the highly doped P-type semiconductor layer 106 doped with Carbon (C) meets with the highly doped N-type semiconductor layer 104 at a junction 110 which pertains more to a tunnel junction structure 102 inside a more complex device 100. However, even with tunnel junction structures 102, the moderately doped P-type layer 60 can be grown above or below the tunnel junction structure 102.

According to the teachings of the present invention, there are cases even when a dopant is not used in a high concentration and its atoms does stay where they were introduced, the special growth conditions necessary for the realization of other components of the device do, nevertheless, cause outdiffusion. We have found experimentally that a tunnel junction structure 102 in which Carbon is used to highly dope the p++ layer 106 is such an example. Zn was only incorporated in the layers leading to the core of the tunnel junction 110, at a dopant concentration of only in the 10¹⁸ level, a level at which its diffusion coefficient should be still low. However, the special growth conditions necessary for the growth of the n++ layer 104 did cause outdiffusion. This outdiffusion lowered the effective doping level in the thin layer 104 which is heavily n doped. Hence, the n++ layer 104 does affect diffusion because of a “kick-out” effect. When the highly doped n-layer 104 is grown, the surface energy level creates an increased concentration of column III interstitial defects. The crystal tries to fix this and pull some Zn near the surface which enhances Zn outdiffusion. This effect becomes more serious when the n-type doping is higher. Hence, to avoid “kick-out” due to pulling Zn near the surface which enhance Zn outdiffusion, with the high n++ layer 104 affecting diffusion more, both the misoriented substrate 240 and the carbon, which is easier to dope with a Group V atom, instead of a Group III atom, in the highly doped P++ layer 106 are both needed. Therefore, even though the diffusion is less on the misoriented substrate 240 than on a conventional (100) substrate, if the high p-type carrier concentration of the P++ layer 106 is obtained by Zn, it still creates a problem that is solvable with the teachings of the present invention.

According to the teachings of the present invention, a combination of all three layers 104, 106, and 60, to provide a high n-type carrier concentration, a high p-type carrier concentration, and a moderate p-type carrier concentration, respectively, is taught for improving device performance. A high concentration is needed on both the N-layer and P-layers, 104 and 106, respectively to create a tunnel current. Therefore, the doping concentrations should be as high as possible in these two layers 104 and 106. Preferably, the at least one highly doped N-type semiconductor layer 104 is doped with an n-dopant member selected from a group consisting of Silicon (Si), Sulfur (S), Selenium (Se), Tin (Sn), Germanium (Ge), Tellurium (Te), and Carbon (C) at a high doping concentration greater than about 10¹⁹ cm⁻³. According to the teachings of the present invention, carbon is introduced in the at least one highly doped P-type semiconductor layer 106 for a high doping concentration greater than about 10¹⁹ cm⁻³.

Although some simple devices requiring highly doped p layers can easily be designed in such a way that C is the only p type dopant, other devices 100 (for example, a VCSEL including a Tunnel Junction) are likely to require p doped layers of materials in which C is not an efficient dopant, such as InP, GaInP, or GaInAsP as the moderately doped moderately doped P-type layer 60. Such layers 60 will need to be doped p-type using another dopant, such as Zn or Be, and it is from those layers 60 that outdiffusion is likely to originate. Preferably, one of the dopants Zn, Be, Cd and Mg is used to achieve a moderate doping concentration of less than about 10¹⁹ cm⁻³ in the moderately doped P-type layer 60.

The moderately doped P-type layer 60 is grown p-type through the intentional incorporation of p-type dopant atoms. It is from this layer 60, doped with a dopant which tends to diffuse, such as Zn, Be, Cd, Mg, that outdiffusion is expected in the at least one highly doped N-type semiconductor layer 104. Outdiffusion from the moderately doped P-type layer 60 threatens the abruptness of a doping profile. A desired abrupt doping profile has no tails and looks perfectly step-like. The profile is always measured perpendicular to the substrate's surface. For example, although one can grow a layer 104 doped n type, followed by a layer 106 doped p type, both with the n and p concentrations as desired, outdiffusion of the p-dopant from the moderately doped P-type layer 60 will create an undesirable tail of concentration of the p-type of dopant atom, which will reach or outdiffuse to the at least one highly doped N-type semiconductor layer 104.

Doping is defined to be the incorporation of a chosen “impurity”, where that “impurity”, or, rather, “dopant atom”, is in a concentration much lower than the concentration of the atoms which compose the layer. For example, the density of In or P atoms in an InP (indium phosphide) layer is approximately 2×10²² per cubic centimeter; the density of the doping atoms is 10¹⁶ to 10²⁰ per cubic centimeter.

Note that, since certain dopant atoms are desired to be incorporated, the word “impurity” it is often not used with the desired dopant atoms because the term “impurity” is reserved for atoms which are incorporated unintentionally.

Without being bound by theoretical understanding of the present invention, the improvement in performance caused by less outdiffusion is due to one or more of the following improvements, as enabled by the teachings of the present invention: a) less outdiffusion, and therefore more abrupt doping profiles; b) ability to introduce a higher dopant concentration without causing outdiffusion; and c) higher effective doping level in adjacent n type doped layers, since the effective doping level is n=n-p=N_{doping}−P_{from outdiffusion}.

It is to be appreciated that all n-type layers are affected by the outdiffusion of the p-dopant from the moderately doped P-type layer 60. Hence, all n-type layers can be higher if there is less out-diffusion. However, if the doping level of an n-type layer does not need to be high, it is not a critical problem in some devices 100. Thus, the present invention focuses on the highly n-type doping layer 104 which should be as high as possible and not on other N-layers that are unreferenced but could also be grown on the substrate 240. The teaching of the present invention is especially effective when devices 100 need a high doping n++ layer 104 since outdiffusion does affect the n++layer's effective doping concentration (because the n-dopant is compensated by an undesired p-dopant).

Basically, the present invention teaches a method for increasing the effective doping level of the least one highly doped N-type semiconductor layer 104, in the semiconductor device 100, by suppressing outdiffusion of dopants from the moderately doped P-type layer 60 to the at least one highly doped N-type semiconductor layer 104. Less diffusion automatically results by using the misoriented substrate 240, as taught by the present invention.

As an example, by choosing a (311) oriented InP or GaAs substrate 240 for the growth of a tunnel junction, an HBT, or another device 100 in which a tunnel junction 102 structure and/or HBT are components, a structure where both C and Zn (or Be) are used as p dopants result: C in the highly doped layer(s) 106, and Zn or Be in the moderately doped layers 60 where C cannot dope efficiently in the reactor, such as in an environment where phosphide compounds (such as InP, GaInAsP, GaInP) are present, or which require special properties incompatible with the growth conditions necessary for sufficient C incorporation.

Growing the highly doped layers 104 and 106 on the misoriented substrate 240 will avoid or at least lead to less outdiffusion of dopants such as Zn or Be, from the moderately doped P-type layer 60 to the highly doped N-type semiconductor layer 104. By this advantage of less outdiffusion being realized with the teachings of the present invention, it may be desirable, and now possible, to raise the doping concentrations above those which had been conventionally determined to be optimal when the devices were grown on the conventional (100) substrates, to further improve the tunnel junction by raising the probability of a high tunnel junction current and lowering its internal series resistance. The performance/reliability of the devices 100 can be verified as usual.

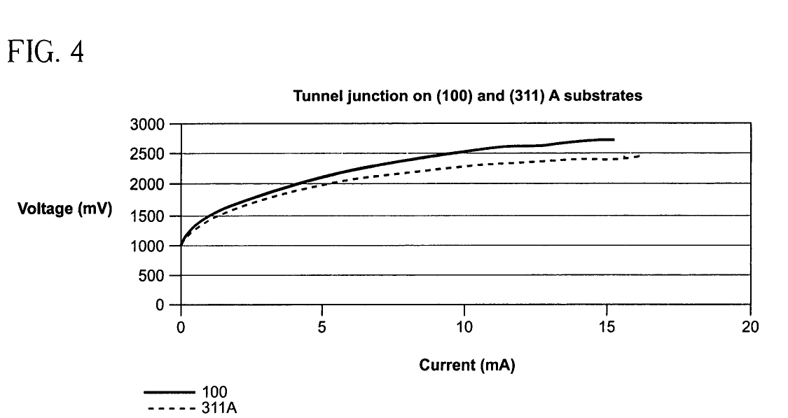

Referring to FIG. 4, the better electrical characteristics of the device 100 grown on a misoriented (311)A substrate 240 is verified. The current-voltage characteristics of light emitting diodes as a device 100 incorporating the tunnel junction structure 102 of FIG. 1 is shown, compared to the same device structure realized on a conventional (100) substrate. In this example, the substrate 240 is a (311)A substrate, which corresponds to the inclination angle of 25 degrees from the (100) plane. Both of the devices were realized on (100) and (311)A InP substrates for growing an AlGaInAs/InP VCSEL with a tunnel junction by OrganoMetallic Vapor Phase Epitaxy and using both C and Zn as p dopants. AlGaInAs quantum well/barriers constitute the light emitting region in both of these devices, and the area of current injection, seven micrometers in diameter, is defined by patterning of a tunnel junction 102. The I-V curves show the lower resistance of the device 100 grown on (311)A substrate 240, reflecting the better electrical characteristics of the tunnel junction 102.

The absence of outdiffusion can be checked by SIMS profiling. In this particular case of a tunnel junction in a VCSEL, the out-diffusion concentration of Zinc in the highly n-doped layer 104 is [Zn]=1.1×10¹⁸ on the (311)A substrate 240 vs. [Zn]=2×10¹⁸ on (100). Hence, a smaller out-diffusion allows the higher desirable n-type carrier concentration for improving device performance. Better mobility for a particular direction on the (311)A substrate 240 may also help to achieve lower resistance.

Along with lower internal series resistance, the device 100 has improved polarization selectivity due to the misoriented substrate 240 lacking the axis of symmetry. Hence, the phenomenon of the lasing polarization switching of VCSELs is an additional device performance improvement. The properties of AlGaInAs/InP VCSELs were improved to the point where they could be used for 10 Gbits/s transmission. The next step for better transmission was to try to fix the VCSELs' polarization state by growing on (311)A substrates 240.

VCSELs grown on the (311)A substrate 240 have properties similar to those of VCSELs grown on (100) in terms of output power and threshold current. As expected, polarization stability was obtained for the (311)A devices 100. Furthermore, the current-voltage characteristics on the (311)A substrate 240 is better due to the tunnel junction described in this invention

Referring back to FIG. 1, for providing further performance improvements to those results from increasing p-type carrier concentration in highly p-doped layer 106 by minimal hydrogen passivation of acceptors and increasing n-type carrier concentration in highly n-doped layer 104 by minimal outdiffusion, the tunnel junction device 100 has the P++-type tunnel junction layer 106 grown over the misoriented substrate 240. Doped with carbon, the first semiconductor material of the P++-type tunnel junction layer 106 preferably includes aluminum (Al), gallium (Ga), arsenic (As) and antimony (Sb). The N++-type tunnel junction layer 104 of a second semiconductor material includes indium (In), gallium (Ga), arsenic (As) and one of aluminum (Al) and phosphorous (P) for providing the tunnel junction 110 between the tunnel junction layers 104 and 106. As already taught, the moderately doped P-type layer 60 is grown over the surface area and has a third semiconductor material doped with a dopant selected as a member from the group consisting of Zn, Be, Cd and Mg. For use as a VCSEL, the misoriented substrate 240 comprises an InP substrate 240 for starting epitaxial growth, the substrate having an upper side, and a lower side opposite the upper side, and being characterized by a substrate bandgap and a substrate lattice constant. Preferably, at least one of the tunnel junction layers 104 or 106 has a thickness ≦30 nm.

All the teachings of the present invention can be applied to different devices 100 that also require a high n-type carrier concentration. For example, amongst all the various possibilities, the tunnel junction structure 102 can be used in a light-emitting device. The light-emitting device can be a light-emitting diode or a laser. The laser can be an edge emitting laser or a vertical cavity surface emitting laser (VCSEL). The device 100 could also be a Hetero Bipolar Transistor (HBT). However, the only change to the teachings of the present invention so far, is that if the device 100 was an HBT, the n++ and p++ layers are not adjacent.

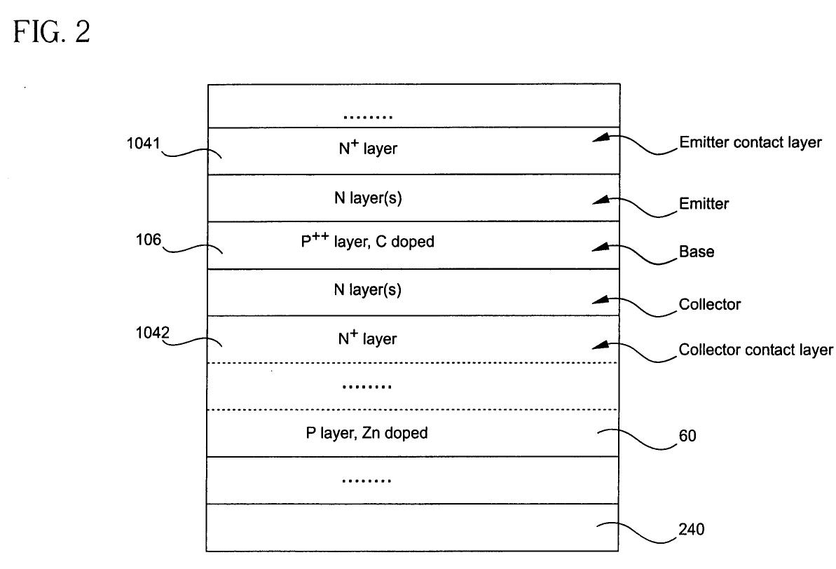

Referring to FIG. 2, the at least one highly doped N-type semiconductor layer 104 of FIG. 1 includes at least two N-type layers 1041 and 1042, serving as the emitter contact and collector contact layers, respectively. The at least one highly doped P-type semiconductor layer is a single P++ layer 106 serving as the base. The single P++ layer 106 is carbon doped and positioned between the at least two N-type layers 1041 and 1042 to form an NPN Hetero Bipolar Transistor (HBT). Similarly, the moderately doped P-type layer 60 can be grown above or below the base or single highly doped layer 106. Thus, the HBT sequence is n+ or n++ emitter contact layer/n emitter/p++base/n− collector/n+ or n++ collector contact layer for an n-p-n HBT, with n replaced by p for a p-n-pHBT.

By growing such devices as described above on misoriented substrates 240, better performance, such as a higher frequency operation for an HBT can be achieved with exactly the same layer structure as used on the more conventional (100) substrates. Because the speed of the HBT is related to the carrier concentration level in the base layer, a higher carrier concentration results in higher speed.

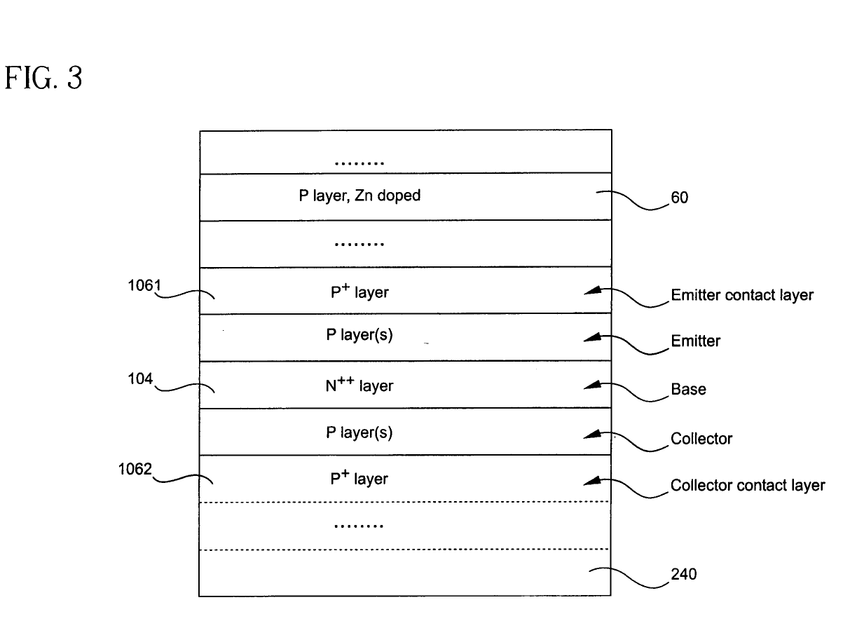

Referring to FIG. 3, the at least one highly doped P-type semiconductor layer 106 includes at least two P-type layers 1061 and 1062, of which at least one of them is doped with carbon, for serving as the emitter contact and collector contact layers, respectively. The at least one highly doped N-type semiconductor is a single N++ layer 104, serving as the base, positioned between the at least two P-type layers 1061 and 1062 to form a PNP Hetero Bipolar Transistor (HBT). Similarly, the moderately doped P-type layer 60 can be grown above or below the base or single highly doped layer 104.

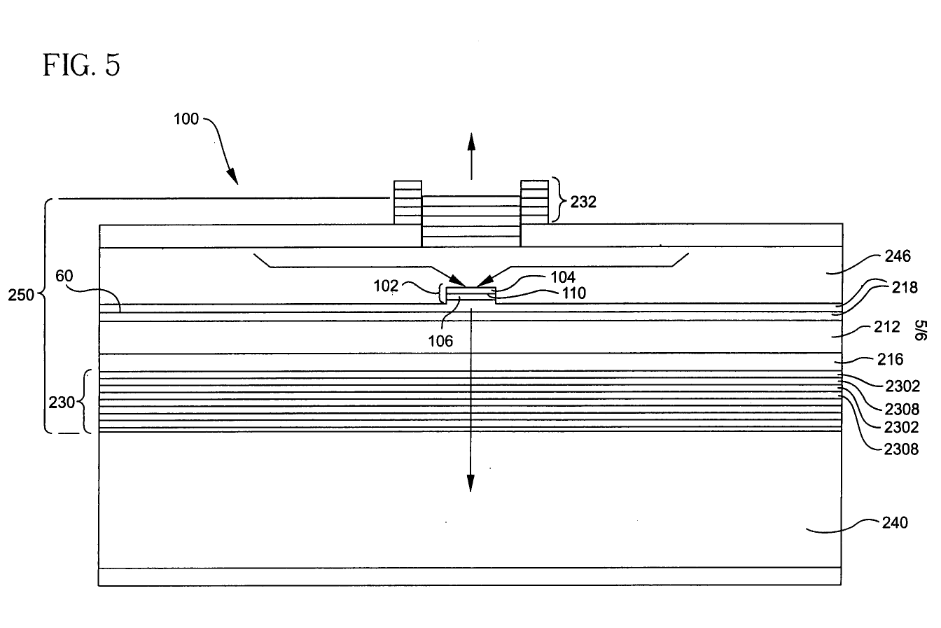

Referring to FIG. 5, the semiconductor device 100 of FIG. 1 is shown with more detail as a light-emitting device, with the tunnel junction structure 102 of FIG. 1 incorporated. A long wavelength VCSEL device 100 operable at wavelengths greater than 1.1 micron is now made possible by using the misoriented InP substrate 240 having a surface area inclined in a range of about 8 to 40 degrees from the {100} plane. The P++-type tunnel junction layer 106 of a first semiconductor material doped with carbon interfaces with the N++-type tunnel junction layer 104 of a second semiconductor material for providing the tunnel junction structure 102 between the tunnel junction layers and the tunnel junction structure 102 is grown over the misoriented substrate 240. The moderately doped P-type layer 60 is grown over the surface area, wherein the moderately doped P-type layer has a third semiconductor material doped with a dopant selected as a member from the group consisting of Zn, Be, Cd and Mg. A semiconductor distributed Bragg reflector (DBR) stack 230 is grown directly over the surface area between the misoriented InP substrate 240 and the tunnel junction structure 102. The semiconductor DBR stack 230 has a plurality of interleaving or alternating high and low index layers, 2308 and 2302, respectively. The material of the low index layer 2302 is InP, and the high index layer 2308 has a material selected from a member of the group consisting of AlGaInAs and GaInAsP. The DBR 230 thus forms a first interference reflector which is deposited to the InP based tunnel junction 102 and an active region 212 after removal of the InP substrate 240.

The misoriented InP substrate 240 has an upper side and a lower side opposite the upper side, and being characterized by a substrate bandgap and a substrate lattice constant. Because the tunnel layers 104 and 106 are grown sufficiently thin, at least one of the tunnel layers can have a strain matched within ±2% of the substrate lattice constant.

It will be appreciated that the InP substrate 240, can optionally be removed, after crystal growth. However, because the InP substrate is needed for crystal growth, the tunnel junction still needs to satisfy the lattice match condition.

The active region 212 is grown over the upper side of the InP substrate 240. The active region 212 has an effective bandgap configured to generate light at a lasing wavelength in response to injected charge from the tunnel junction structure 102. By design, the active region 212 is structured to generate light having a wavelength between 1.1 and 2 micron.

The first interference reflector 230, which strongly reflects light at the lasing wavelength, is disposed near, if not directly, the InP substrate 240 and remote from the tunnel junction structure 102. A second interference reflector 232 is disposed remote from the first interference reflector 230 and near the tunnel junction structure 102. The second interference reflector 232 substantially reflects light at the lasing wavelength generated by the active region 212 disposed between the first and second interference reflectors 230 and 232.

An optical distance between the opposed ends of the first and second interference reflectors 230 and 232 being in a predetermined relationship with the lasing wavelength forms a vertical optical cavity 250 for a vertical cavity surface emitting laser (VCSEL). To provide the required optical distance, one or more spacers are disposed between the first and second interference reflectors 230 and 232. For example, a substrate-side spacer layer 216 and a remote-side spacer layer 218 sandwiches the active region 212 while a tunnel junction spacer layer 246 surrounds the tunnel junction structure 102. By design, the optical cavity 250 is now resonant at the lasing wavelength of the light generated in the active region 212 and provides higher power, such as 2mW in an exemplary built device an a wavelength between 1.1-2 micron.

With the misoriented substrate 240, specifically a (311)A substrate 240 was used as an example, there is an additional surprise finding that there is now less diffusion of the phosphorous (P) from the InP low index layer 2302 in the semiconductor mirror 230 on the (311)A substrate 240. Nobody has yet to report less diffusion of the phosphorous from InP to AlGaInAs on the (311)A substrate 240. Note that the phosphorous in InP is a layer material in the main DBR stack, which is different from the outdiffusion dopant atom from the moderately doped p-type layer 60.

One of the problems of long wavelength VCSEL is how to achieve high reflectivity with a semiconductor DBR. To obtain high reflectivity, a larger index difference, as much as possible, is needed between the two alternating layers in the DBR 230. In one example, an AlGaInAs/InP DBR 230 was used, which has the highest index difference in the material combination that can be grown on InP substrate by MOCVD. However, the index difference is still smaller than that of AlGaAs/GaAs for GaAs-based DBRs. Making it worse, it is known that the phosphorous P in InP and As in AlGaInAs intermixes at the interfaces. Phosphorous P in the low index layers 2302, especially diffuses to the high index AlGaInAs layers 2308, which results in a poor interface (lowering reflectivity). However to our surprise, we found this P diffusion to be less on the (311)A substrate 240.

Hence, according to the teachings of the present invention when the DBR 230 is grown which have different ratios of “P” and “As” between the two layers 2302 and 2308, we can achieve a better interface profile on the misoriented substrate 240, which results in higher reflectivity. The higher reflectivity provides lower threshold and higher output power to the mirror 232 on other side.

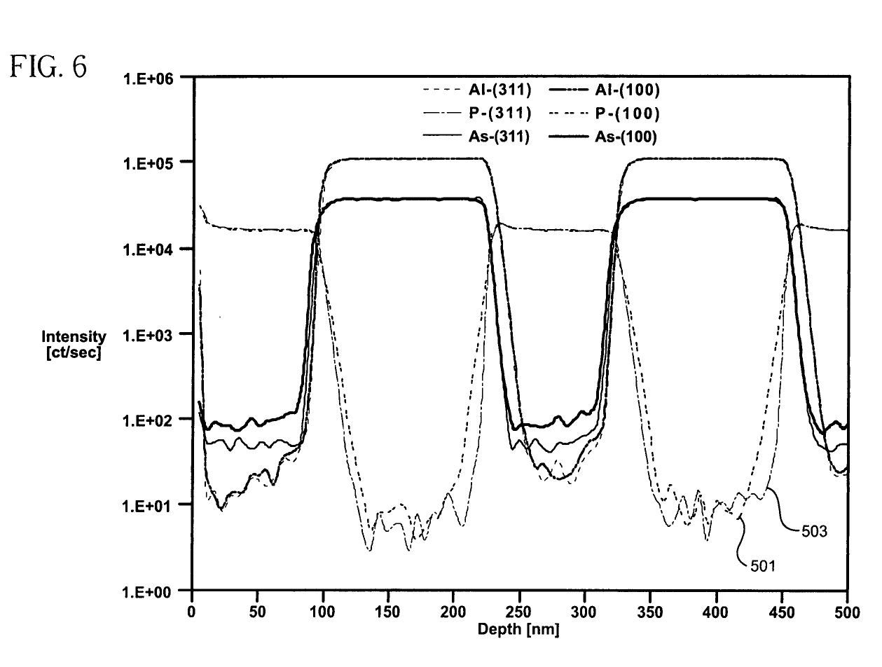

Referring to FIG. 6, we observed a sharper decay of the P concentration in a secondary ion mass spectrometry (SIMS) profile. The SIMS profile measures the abruptness of an atom profile. The curve 503 is the profile of phosphorous (P) using the (311) substrate 240 and the curve 501 is P using the conventional substrate (100). The decay for the (311) substrate 240 as seen in curve 503 is much tighter or more abrupt, which means there is less diffusion.

It will be apparent to those skilled in the art that various modifications and variations can be made to the present invention without departing from the spirit and scope of the invention, such as growing a DBR on the InP misoriented substrate alone to form a mirror or a micro-resonant cavity laser, or any other semiconductor device on a misoriented InP substrate. Thus it is intended that the present invention cover the modifications and variations of this invention provided they come within the scope of the appended claims and their equivalents.

1. A semiconductor device comprising:
a misoriented substrate having a surface area inclined in a range of about 8 to 40 degrees from the {100} plane;
at least one highly doped P-type semiconductor layer of a first semiconductor material doped with Carbon (C) grown over the surface area;
at least one highly doped N-type semiconductor layer of a second semiconductor material grown over the surface area and near the at least one highly doped P-type semiconductor layer; and
a moderately doped P-type layer is grown over the surface area, wherein the moderately doped P-type layer has a third semiconductor material doped with a dopant selected as a member from the group consisting of zinc (Zn), beryllium (Be), cadmium (Cd) and magnesium (Mg).

2. The device of claim 1, wherein Carbon is introduced in the at least one highly doped P-type semiconductor layer for a high doping concentration greater than about 10¹⁹ cm⁻³.

3. The device of claim 1, wherein the member from the group consisting of Zn, Be, Cd and Mg is used to achieve a moderate doping concentration of less than about 10¹⁹ cm⁻³.

4. The device of claim 1, wherein the at least one highly doped N-type semiconductor layer is doped with an n-dopant member selected from a group consisting of silicon (Si), sulfur (S), selenium (Se), tin (Sn), germanium (Ge), tellurium (Te), and carbon (C) at a high doping concentration greater than about 10¹⁹ cm⁻³.

5. The device of claim 1, wherein the first semiconductor material is a compound of a first member selected from the group consisting of aluminum (Al), gallium (Ga), and indium (In) and a second member selected from the group consisting of arsenic (As), nitrogen (N), and antimony (Sb).

6. The device of claim 1, wherein the second semiconductor material is a compound of a first member selected from the group consisting of aluminum (Al), gallium (Ga), and indium (In) and a second member selected from the group consisting of arsenic (As), nitrogen (N), phosphorous (P), and antimony (Sb).

7. The device of claim 1, wherein each of the first, second, and third semiconductor material is a compound of a first member selected from the group consisting of aluminum (Al), gallium (Ga), and indium (In) and a second member selected from the group consisting of arsenic (As), nitrogen (N) phosphorous (P), and antimony (Sb).

8. The device of claim 1, wherein the misoriented substrate is made from a member selected from the group consisting of InP, GaAs, InAs, GaSb, and GaP.

9. The device of claim 1, wherein the at least one highly doped P-type semiconductor layer comprises at least two P-type layers and the at least one highly doped N-type semiconductor comprises an N++ layer positioned between the at least two P-type layers to form a PNP Hetero Bipolar Transistor (HBT).

10. The device of claim 1, wherein the at least one highly doped N-type semiconductor layer comprises at least two N-type layers and the at least one highly doped P-type semiconductor layer comprises a P++ layer positioned between the at least two N-type layers to form an NPN Hetero Bipolar Transistor (HBT).

11. The device of claim 1, wherein the at least one highly doped P-type semiconductor layer is adjacent to the at least one highly doped N-type semiconductor layer to form a tunnel junction.

12. The device of claim 11, wherein the device comprises a light-emitting device including the tunnel junction.

13. The device of claim 12, wherein the light-emitting device is a light-emitting diode.

14. The device of claim 12, wherein the light-emitting device is a laser.

15. The device of claim 14, wherein the laser is an edge emitting laser.

16. The device of claim 15, wherein the laser is a vertical cavity surface emitting laser (VCSEL).

17. The device of claim 16, wherein the VCSEL has improved polarization selectivity due to the misoriented substrate lacking the axis of symmetry.

18. A method of increasing the effective doping level of at least one highly doped N-type semiconductor layer, in a semiconductor device, by suppressing outdiffusion of dopants to at least one highly doped N-type semiconductor layer, the method comprising the steps:
providing a misoriented substrate having a surface area inclined in a range of about 8 to 40 degrees from the {100} plane;
growing at least one highly doped P-type semiconductor layer of a first semiconductor material doped with Carbon (C) with a carbon concentration in a range greater than about 1×10¹⁹ cm⁻³ over the surface area;
growing at least one-highly doped N-type semiconductor layer of a second semiconductor material over the surface area and near the at least one highly doped P-type semiconductor layer;
growing a moderately doped P-type layer of a third semiconductor material over the surface area; and
doping the moderately doped P-type layer with a dopant selected from a member from the group consisting of Zn, Be, Cd and Mg.

19. A long wavelength VCSEL device, the device comprising:
a misoriented InP substrate having a surface area inclined in a range of about 8 to 40 degrees from the {100} plane;
a P++-type tunnel junction layer of a first semiconductor material doped with carbon;
an N++-type tunnel junction layer of a second semiconductor material for providing a tunnel junction structure between the tunnel junction layers and the tunnel junction structure is grown over the misoriented substrate;
a moderately doped P-type layer grown over the surface area, wherein the moderately doped P-type layer has a third semiconductor material doped with a dopant selected as a member from the group consisting of Zn, Be, Cd and Mg; and
a semiconductor distributed Bragg reflector (DBR) stack grown directly over the surface area between the misoriented InP substrate and the tunnel junction structure, the semiconductor DBR stack having a plurality of alternating high and low index layers, wherein the material of the low index layer is InP, and the high index layer has a material selected from a member of the group consisting of AlGaInAs and GaInAsP.

20. The device of claim 19, wherein the first semiconductor material includes aluminum (Al), gallium (Ga), arsenic (As) and antimony (Sb) and the second semiconductor material includes indium (In), gallium (Ga), arsenic (As) and one of aluminum (Al) and phosphorous (P).
